(19) United States
(12) Patent Application Publication
(10) Pub. No.: US 2008/0117710 A1
(43) Pub. Date: May 22, 2008

(54) LOOK-UP TABLE CASCADE CIRCUIT, LOOK-UP TABLE CASCADE ARRAY CIRCUIT AND A PIPELINE CONTROL METHOD THEREOF

(75) Inventor: Kazuhiko KAJIGAYA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 11/942,278

(22) Filed: Nov. 19, 2007

(30) Foreign Application Priority Data
Nov. 20, 2006 (JP) 2006-313637

(51) Int. Cl. G11C 8/00

(52) U.S. Cl. 365/230.06; 365/231; 365/233.1

(57) ABSTRACT

A look-up table cascade circuit having N look-up tables connected in cascade for implementing a desired logic function, comprising: N memory cell arrays for storing data of the look-up table in memory cells; N input select circuits for selecting a word line and bit lines to specify memory cells based on an input variable to the look-up table; N output circuits for selectively coupling data in the memory cells selected by the input select circuit to an input/output path and for outputting the data as an output variable of the look-up table; and N−1 connection circuits arranged between each preceding output circuit and each subsequent input select circuit, for receiving an external input variable and the output variable output from each preceding output circuit, and for selectively distributing all or part of an external output variable and the input variable based on connection information.

### BACKGROUND OF THE INVENTION

1. Field of the Invention

The present invention relates to a look-up table cascade circuit in which a plurality of look-up tables for implementing a desired logic function are connected in cascade, and particularly relates to a look-up table cascade circuit configured using a general memory circuit, and a look-up table cascade array circuit in which the look-up table cascade circuits are arranged in an array form.

2. Description of the Related Art

In recent years, in order to realize LSI having various functions, techniques for configuring a look-up table (LUT) on a memory have been proposed (for example, see “On Look-Up Table Cascade Architecture” IEEJ (The Institute of Electrical Engineers of Japan) Electronics, Information and Systems Society MC2-4, Aug. 29 and 30, 2003; Yukihiro Iguchi and Tsutomu Sasao). In this technique, a LUT cascade circuit in which LUTs are connected in multiple stages in cascade is disclosed to perform a complicated function. By employing such a LUT cascade circuit, each LUT has a configuration in which a large scale logic function having many inputs/outputs is divided into a plurality of relatively small-scale logic functions, so that data amount of the LUT can be suppressed and the chip area can be reduced.

According to the proposed technique, a sequential circuit method and a combinational circuit method are known as two architectures for the LUT cascade circuit. The sequential circuit method is a technique for configuring a plurality of LUTs integrally in one memory, and for accessing the memory repeatedly for each stage of the cascade by a sequencer. For example, a configuration employing this method is proposed in Japanese Patent Laid-Open No. 2004-258799. Meanwhile, the combinational circuit method is a technique for transmitting a signal sequentially through a large number of series connected LUTs in multiple stages and for extracting a target signal from the last stage. Flexible control can be performed by employing the sequential circuit method, but it is a problem that high-speed operation is difficult because of using the sequencer. Thus, if the high-speed operation is required, employment of the LUT cascade circuit based on the combinational circuit method is desirable.

When using the LUT cascade circuit based on the above combinational circuit method, a structure in which the number of signal lines connecting adjacent LUTs can be flexibly changed is desirable. Therefore, in the reference by Iguchi et al., a configuration is disclosed in which a large number of LUTs are connected in series in multiple stages and the number of signals output to subsequent stages and the number of signals output to outside, both of which are included in the total number of outputs of the preceding stage and inputs from the outside, can be freely switched by a connection circuit disposed between adjacent LUTs. Thereby, signals can be freely transferred between the LUTs and the signals in the middle of an operation can be freely extracted to the outside, so that a highly flexible structure of the LUT cascade circuit can be realized.

However, when actually configuring the LUT cascade circuit based on the combinational circuit method, since each LUT connected in cascade does not correspond to a general input/output interface, a special-purpose memory circuit having the above input/output structure needs to be implemented. Further, in order to realize the highly flexible structure using the above connection circuit, configuration and control for switchingly connecting a large number of input/output signals become complicated. Furthermore, since this configuration assumes read operation for each LUT included in the LUT cascade circuit, it is not easy to rewrite the LUT by writing operation of desired data. Particularly, when the number of stages of the LUT cascade circuit becomes large, it is a problem that the scale of the entire circuit including a large number of LUTs and a large number of connection circuits increases and complexity in control arises.

Meanwhile, it is desirable that a plurality of the LUT cascade circuits is arranged in parallel in LSI as well as a single LUT cascade circuit in order to achieve various functions. However, when signal lines or control signals from/to the outside are commonly used in the above conventional combinational circuit method, it is difficult to operate the LUT cascade circuits different from one another simultaneously. Accordingly, when arranging the plurality of the LUT cascade circuits, it is difficult to employ pipeline control having an advantage in operating speed.

### BRIEF SUMMARY OF THE INVENTION

An object of the present invention is to provide a LUT cascade circuit capable of freely writing with convenience and simplicity in configuration and control when configuring the LUT cascade circuit based on the combinational circuit method in which a plurality of LUTs configured in a general memory circuit are connected in cascade with a flexible input/output structure, and to provide a LUT cascade array circuit capable of high-speed processing in which the LUT cascade circuits are operated in parallel by pipeline control.

An aspect of the present invention is a look-up table cascade circuit having N (N is an integer greater than or equal to two) look-up tables connected in cascade for implementing a desired logic function, comprising: N memory cell arrays each for storing data of each said look-up table in a plurality of memory cells formed at intersections between a plurality of word lines and a plurality of bit lines; N input select circuits each for selecting a word line and one or more bit lines to specify one or more memory cells to be read in each said memory cell array based on an input variable to each said look-up table; N output circuits each for selectively coupling data of a predetermined number of bits in the memory cells selected by each said input select circuit to an input/output path and for outputting the data as an output variable of each said look-up table; and N−1 connection circuits arranged between each preceding said output circuit and each subsequent said input select circuit respectively included in stages connected in cascade, each for receiving an external input variable and the input variable output from each preceding said output circuit, and each for selectively distributing all or part of an external output variable and the input variable to be supplied to each subsequent said input select circuit based on preset connection information.

According to the configuration of the present invention, the look-up table is configured by the memory cell array, the input select circuit and the output circuit in each stage of the look-up table cascade circuit, and the external input/output signals and the internal input variable are selectively distributed by the connection circuit arranged between the stages. Thereby, it is possible to configure the look-up table cascade circuit based on a combinational circuit method having a highly flexible input/output structure, by adding a small circuit to basic elements of a general memory circuit. In this case, it is possible to flexibly adjust data to be output to outside and data to be transmitted to the subsequent stage, both of which are among the output variable of the look-up table at a predetermined position, by appropriately setting the connection information given to the connection circuit. Particularly, when a large number of look-up tables are used, it is suitable for a configuration capable of operating at high speed with a small circuit scale.

In the present invention, each said connection circuit may include: an input register for storing the external input variable and the external output variable; a shifter circuit for shifting data stored in the input register by a shift amount included in the connection information; and an output register for storing the data shifted by the shifter circuit and for outputting the external output variable and the input variable.

In the present invention, each said input select circuit may include: a row decoder for selectively activating the plurality of word lines; and a column decoder for selecting a predetermined number of the bit lines to specify the memory cells to be read.

In the present invention, a word line hierarchy structure including a plurality of main word lines and a plurality of sub-word lines may be formed in said memory cell array, and the row decoder may include a main row decoder for selectively activating the plurality of main word lines and one or more sub decoders for selectively activating the plurality of sub-word lines.

In the present invention, the input variable may comprise a first input variable input from the connection circuit to the column decoder, a second input variable input from the connection circuit to the sub decoders, and a third variable input form outside to the main row decoder.

In the present invention, two sub decoders may be arranged symmetrically at both ends in a word line extending direction of each said memory cell array, and the plurality of sub-word lines may be alternately connected to the sub decoders.

In the present invention, said output circuit may include an output switch circuit for selectively connecting a predetermined number of the bit lines selected by said input select circuit to the input/output path, and an output latch circuit for latching the output variable through the input/output path.

In the present invention, data can be input or output from/to said memory cell array along a path through the input/output path which is different from a path through the output latch circuit.

In the present invention, an input/output bit configuration of said memory cell array can be changed within a range of bit widths of the input/output path.

In the present invention, said N look-up tables may be configured using N DRAM circuits.

Meanwhile, an aspect of the present invention is a look-up table cascade array circuit having M (M is an integer greater than or equal to two) look-up table cascade circuits arranged in an array form in a word line extending direction, wherein in M said memory sell arrays at the same position of different said look-up table cascade circuits, the external input variable is transmitted along a common path and the external output variable is transmitted along a common path.

Further, an aspect of the present invention is a look-up table cascade array circuit having M (M is an integer greater than or equal to two) look-up table cascade circuits arranged in an array form in a word line extending direction, wherein M said memory sell arrays at the same position of different said look-up table cascade circuits share the plurality of main word lines, and a selected main word line is activated in response to the input variable commonly input from outside.

Furthermore, an aspect of the present invention is a pipeline control method of a look-up table cascade array circuit for performing pipeline control for the look-up table cascade array circuit in a predetermined order, comprising the steps of: performing operations for two said look-up tables at the same position of two successive said look-up table cascade circuits, including the steps of: performing a first operation in which a first look-up table is selected to operate said input select circuit at a first timing, and the output variable is output from said output circuit so as to be transmitted to a subsequent stage after a predetermined delay time elapses from the first timing; and performing a second operation in which a second look-up table is selected to operate said input select circuit at a second timing before the predetermined delay time elapses, and the output variable is output from said output circuit so as to be transmitted to a subsequent stage after a predetermined delay time elapses from the second timing; and repeating the operations for all the look-up tables in the same manner, in which the first operation is performed for each preceding look-up table and the second operation is performed for each subsequent look-up table.

In this case, the first and second operations for each of said M look-up table cascade circuits may be controlled in synchronization with a clock signal having a predetermined period, and a time difference between the first and second timings may be equal to one period of the clock signal.

As described above, according to the present invention, the look-up table cascade circuit is configured using a general memory circuit and its additional circuit in which the memory cell arrays, the input select circuits, the output circuits and the connection circuits are arranged. Based on the input variable distributed by the connection circuit in accordance with the output variable from the preceding stage and the external input variable, a bit line and a word line are selected for data to be read in each memory cell. In this case, the look-up table of each stage has a flexible input/output structure, which can be freely changed in accordance with a setting of the connection information for the connection circuit. Accordingly, an efficient and highly integrated look-up table cascade circuit can be configured without complexity in circuit configuration and control, and write operation for each look-up table can be freely performed by utilizing the input/output path different from the connection circuit in the memory circuit.

Further, the look-up table cascade array circuit capable of performing various functions can be achieved by arranging the look-up table cascade circuits of the present invention in an array form. In this case, the look-up tables at the same position of different cascade connections can share the word line or the signal path, thereby achieving operations under the pipeline control. Accordingly, different look-up table cascade circuits can be operated in parallel, thereby improving the effective operation speed.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a block diagram showing a basic configuration of a unit LUT circuit included in a LUT cascade circuit of a first embodiment;

FIG. 2 is a diagram showing a configuration of a selector circuit of the unit LUT circuit;

FIG. 3 is a diagram explaining an example of a shift operation of a shifter circuit of the selector circuit;

FIG. 4 is a block diagram showing a configuration example of the LUT;

FIG. 5 is a diagram showing a modification of the LUT of FIG. 4;

FIG. 6 is a diagram showing a schematic configuration of an output switch circuit;

FIG. 7 is a diagram showing selection operation of a column decoder;

FIG. 8 is a diagram showing a specific configuration example of an output switch circuit of FIG. 6;

FIG. 9 is a diagram showing a circuit configuration of sub decoders;

FIG. 10 is a block diagram showing a configuration example of a LUT cascade circuit in which N unit LUT circuits are connected sequentially;

FIG. 11 is diagram showing an entire configuration of a programmable logic LSI as an example of a semiconductor device of the first embodiment;

FIG. 12 is a block diagram showing a configuration of a logic block of FIG. 11;

FIG. 13 is a block diagram showing a configuration of a connecting circuit of FIG. 11;

FIG. 14 is a diagram showing a circuit configuration of sub decoders of a second embodiment;

FIG. 15 is a diagram showing a configuration example of a LUT cascade array circuit in which two LUT cascade circuits each having N unit LUT circuits connected sequentially are arranged in an array form in the second embodiment;

FIG. 16 is a waveform diagram corresponding to pipeline control in which a read operation for two LUTs adjacent in a longitudinal direction of FIG. 15 is exemplified;

FIG. 17 is a diagram showing a temporal transition of read operations for the unit LUT circuits constituting a plurality of LUT cascade circuits of the second embodiment in which the pipeline control is not performed;

FIG. 18 is a diagram showing a temporal transition of read operations for the unit LUT circuits constituting a plurality of LUT cascade circuits of the second embodiment in which each LUT cascade circuit is operated one time by the pipeline control; and

FIG. 19 is a diagram showing a temporal transition of read operations for the unit LUT circuits constituting a plurality of LUT cascade circuits of the second embodiment in which the LUT cascade circuit are repeatedly operated by the pipeline control.

### DETAILED DESCRIPTION OF THE INVENTION

Preferred embodiments of the present invention will be described with reference to the accompanying drawings. Hereinafter, two embodiments will be described in which a look-up table (hereinafter referred to as “LUT”) cascade circuit is configured by connecting a plurality of LUTs in multiple stages using a memory circuit such as DRAM.

### First Embodiment

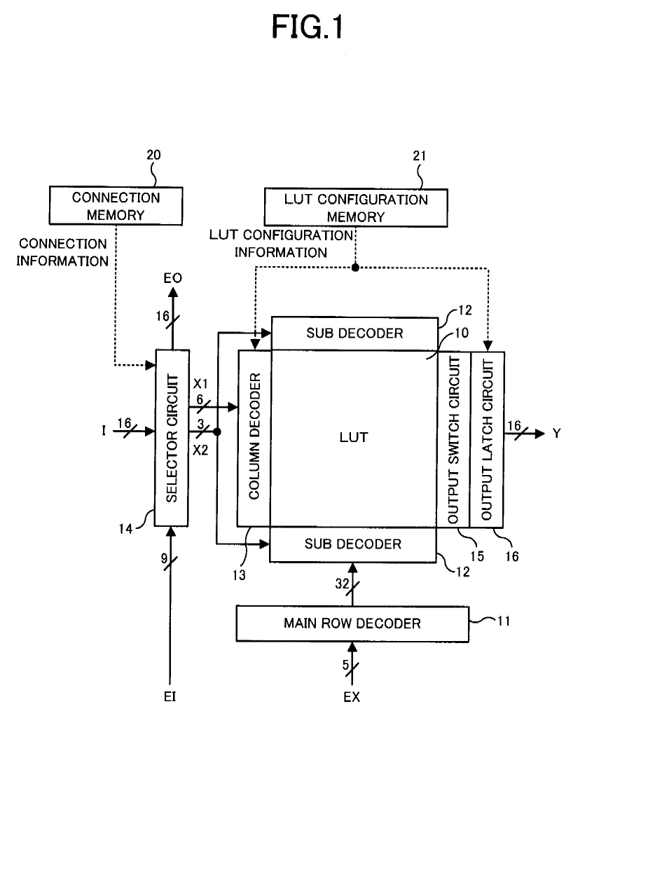

In a first embodiment, a case will be described in which a LUT cascade circuit having a plurality of LUTs connected in multiple stages is implemented. FIG. 1 a block diagram showing a basic configuration of a unit LUT circuit included in the LUT cascade circuit of the first embodiment. The unit LUT circuit shown in FIG. 1 includes, for example, a circuit required for the function of the LUT, which is added to constituent elements of a general DRAM.

As shown in FIG. 1, the unit LUT circuit includes a LUT 10 configured in a memory cell array, a main row decoder 11, two sub decoders 12, a column decoder 13, s selector circuit 14, an output switch circuit 15 and an output latch circuit 16. Further, a connection memory 20 for storing connection information and a LUT configuration memory 21 for storing LUT configuration information are arranged on the periphery of the unit LUT circuit.

The unit LUT circuit of FIG. 1 serves as a predetermined logic function. A 16-bit output variable transmitted from a preceding stage of the LUT cascade circuit is input as an input signal I to the selector circuit 14, and a 9-bit external input variable EI is input to the selector circuit 14 from outside. The selector circuit 14 divides the input 25 bits into a 16-bit external output variable EO, a 6-bit input variable X1 (a first input variable) and a 3-bit input variable X2 (a second input variable), and outputs them, as described later. Further, a 5-bit external input variable EX (a third input variable) from outside is input to the main row decoder 11. The input variables X1, X2 and the external input variable EX integrally constitute a 14-bit input variable supplied to the LUT. Meanwhile, a 16-bit output variable Y is output from the latch circuit 16 to the subsequent stage of the LUT cascade circuit.

The memory cell array in which the LUT 10 is configured includes a large number of memory cells formed at intersections between a plurality of bit lines and a plurality of word lines intersecting therewith. Each memory cell stores one bit of the LUT data according to the logic function. A word line to be accessed in the LUT 10 is selected by the main row decoder 11 and the two sub decoders 12 based on a word line hierarchy structure. Further, a bit line to be accessed in the LUT 10 is selected by the column decoder 13. The main row decoder 11, the sub decoders 12 and the column decoder 13 integrally serve as an input select circuit of the invention. In addition, specific configuration and operation of the memory cell array and the respective decoders will be described later.

The selector circuit 14 which serves as a connection circuit of the invention receives the above 25 bits consisting of the input signal I and the external input variable EI, and selectively distributes data shifted by a predetermined shift amount based on the connection information supplied from the connection memory 20. Among the shifted data, the 16-bit external output variable EO is output to outside, the 6-bit input variable X1 is output to the column decoder 13, and the 3-bit input variable X2 is output to the two sub decoders 12.

The output switch circuit 15 is a circuit for switching an input/output path for 16-bit data to be accessed in the LUT 10 based on the LUT configuration information supplied from the LUT configuration memory 21, and for selectively connecting the input/output path to a 16-bit input/output bus. The output latch circuit 16 is a circuit for latching the 16-bit data output from the output switch circuit 15 to the input/output bus and for outputting the data to the subsequent circuit. In the first embodiment, an input/output bit configuration (data width) in accessing the memory cell array can be selectively set to any one of a 4-bit configuration, an 8-bit configuration and a 16-bit configuration, and data having the input/output bit configuration set under the later described control is output to the subsequent LUT 10. The output switch circuit 15 and the output latch circuit 16 integrally serve as an output circuit of the invention.

Here, another path connected to the output switch 15 through the input/output bus can be provided separately from the path from the output switch circuit 15 to the subsequent stage through the output latch circuit 16, which are not shown in FIG. 1. By using such a path, write data from outside can be written to the memory cell array from the input/output bus through the output switch 15. Thereby, contents of each LUT 10 can be freely rewritten.

A logic function of 14 inputs/16 outputs can be implemented by the unit LUT circuit shown in FIG. 1. The 14-bit input variable of the logic function includes the 6-bit input variable X1, the 3-bit input variable X2 and the 5-bit external input variable EX. Among these, 9 bits of the input variables X1 and X2 are distributed from the output variable Y of the preceding stage and the external input variable EI by the selector circuit 14 which sets an arbitrary number of distributed bits for each variable. Further, the 16-bit output variable of the logic function corresponds to the output variable Y output from the output latch circuit 16, and an arbitrary number of bits thereof can be extracted as the external output variable EO from the selector circuit 14 of the subsequent stage.

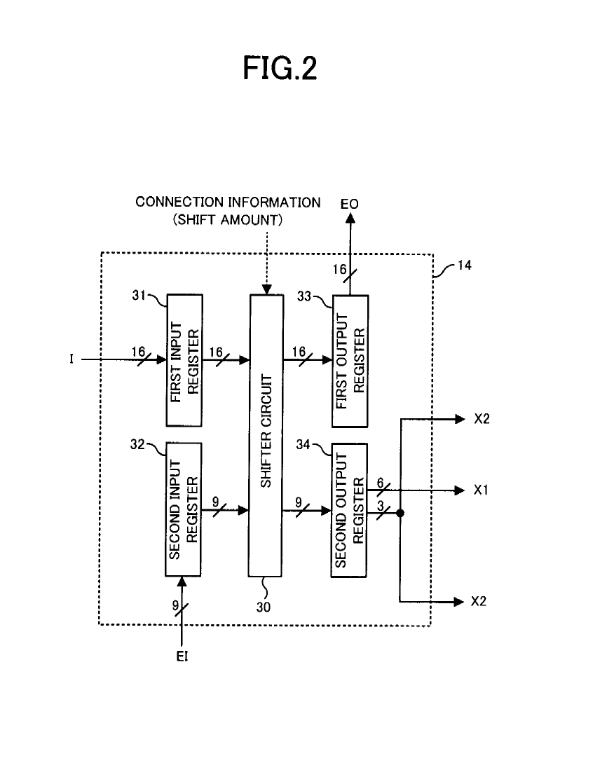

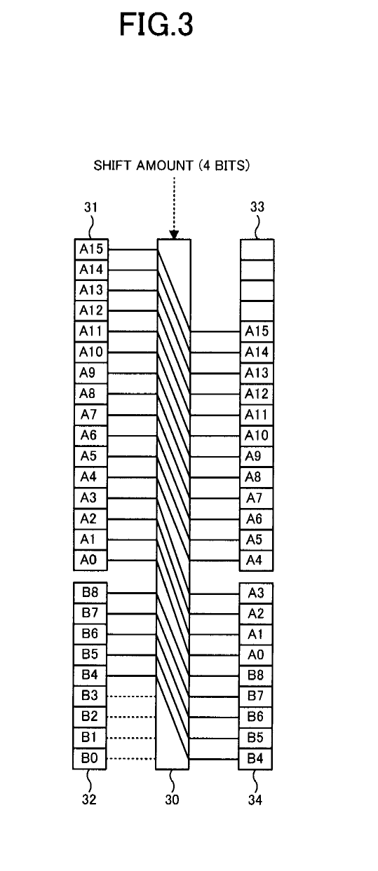

Next, configuration and operation of the selector circuit 14 at the input-side of the LUT 10 will be described with reference to FIGS. 2 and 3. The selector circuit 14 as shown in FIG. 2 includes a shifter circuit 30, a first input register 31 and a second input register 32 at the input-side of the shifter circuit 30, a first output register 33 and a second output register 34 at the output-side of the shifter circuit 30. The first input register 31 is a 16-bit register for storing the 16-bit input signal I received from the preceding stage, and the second input register 32 is a 9-bit register for storing the 9-bit external input variable EI received from outside.

The shifter circuit 30 receives 25 bits consisting of 16 bits stored in the first input register 31 and 9 bits stored in the second input register 32, and shifts the input 25 bits in a downward direction in FIG. 2 at a predetermined timing in accordance with the shift amount as the connection information from the connection memory 20. When the shift operation of the shifter circuit 30 is performed, 16 bits among the shifted 25 bits are output to the first output register 33, and the remaining 9 bits are output to the second output register 34. The 16 bits of the first output register 33 are output to outside as the external output variable EO. Meanwhile among the 9 bits of the second output register 34, 6 bits are output to the column decoder 13 as the input variable X1, and 3 bits are output commonly to the two sub decoders 12 as the input variable X2.

Here, an example of the shift operation of the shifter circuit 30 will be described using FIG. 3. FIG. 3 shows an example in which the shift amount is set to four bits. If the shift amount is set to zero, data stored in the first input register 31 is sent to the first output register 33 and data stored in the second input register 32 is sent to the second output register 34, respectively through the shifter circuit 30. As shown in FIG. 3, the input signal I consists of 16 bits A0 to A15, and the external input variable EI consists of 9 bits B0 to B8. In this case, when 4-bit shift operation is performed in the shifter circuit 30, upper 12 bits A4 to A15 of the input signal I are stored in lower 12 bits of the first output register 33, while upper 4 bits of the first register 33 are maintained in a state of “don't care”. Further, lower 4 bits A0 to A3 of the input signal I are stored in upper 4 bits of the second output register 34, and upper 5 bits B4 to B8 of the external input variable EI are stored in lower 5 bits of the second output register 34, however lower 4 bits B0 to B3 of the external output variable EO are lost by the shift operation of the shifter circuit 30.

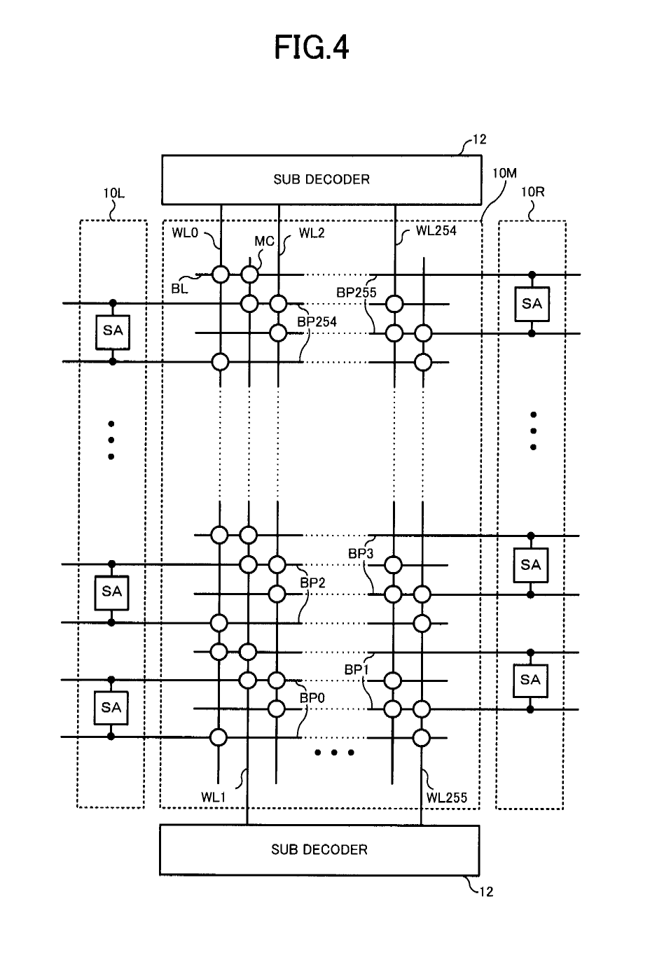

Next, a configuration example of the LUT 10 will be described with reference to FIG. 4. In the example of FIG. 4, a specific configuration including a memory cell array 10M of a general DRAM and rows of sense amplifiers 10L and 10R arranged on both sides of the memory cell array 10N are shown. In the memory cell array 10M, a plurality of word lines WL and a plurality of bit lines BL intersecting therewith are arranged, and a large number of memory cells MC are formed at intersections between the word lines WL and the bit lines BL. Two bit lines BL as a set constitute a bit line pair BP. In the example of FIG. 4, a single memory cell MC is formed at one of two intersections between each bit line pair BP and one word line WL. The arrangement pattern for the intersections of memory cells MC of FIG. 4 is an example, so various arrangement patterns capable of storing the same data can be employed.

As shown by numbers in parentheses added to the bit line pairs BP of FIG. 4, 256 bit line pairs BP0 to BP255 are alternately connected to each sense amplifier SA of the rows of sense amplifiers 10L and 10R on the both sides. That is, 128 even numbered bit line pairs BP are connected to the sense amplifiers SA of the left side row of sense amplifiers 10L, and 128 odd numbered bit line pairs BP are connected to the sense amplifiers SA of the right side row of sense amplifiers 10R. Each sense amplifier SA has two input terminals connected between two bit lines BL of the bit line pair BP, and operates to amplify a minute potential of the bit line pair BP generated due to accumulate charge of the memory cell MC to rewrite it to the memory cell MC.

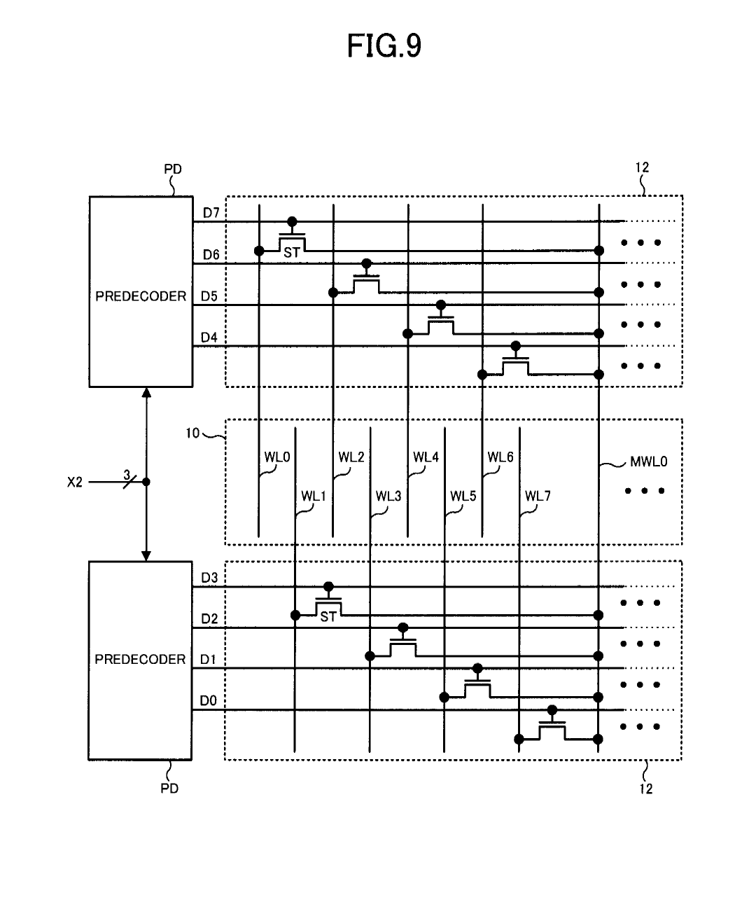

The above two sub decoders 12 are arranged symmetrically at both ends in a word line extending direction of the memory cell array 10M. As shown by numbers in parentheses added to the word lines WL, 256 word lines WL are alternately connected to the sub decoders 12 on both sides. That is, 128 even numbered word lines WL are connected to the upper sub decoder 12, and 128 odd numbered word lines WL are connected to the lower sub decoder 12. 32 main word lines MWL (see FIG. 9) are connected to the upper and lower two sub decoders 12 as described later, and operation is performed such that one of every 8 word lines (sub-word lines) WL is selectively connected to the main word line MWL in accordance with the input variable X2.

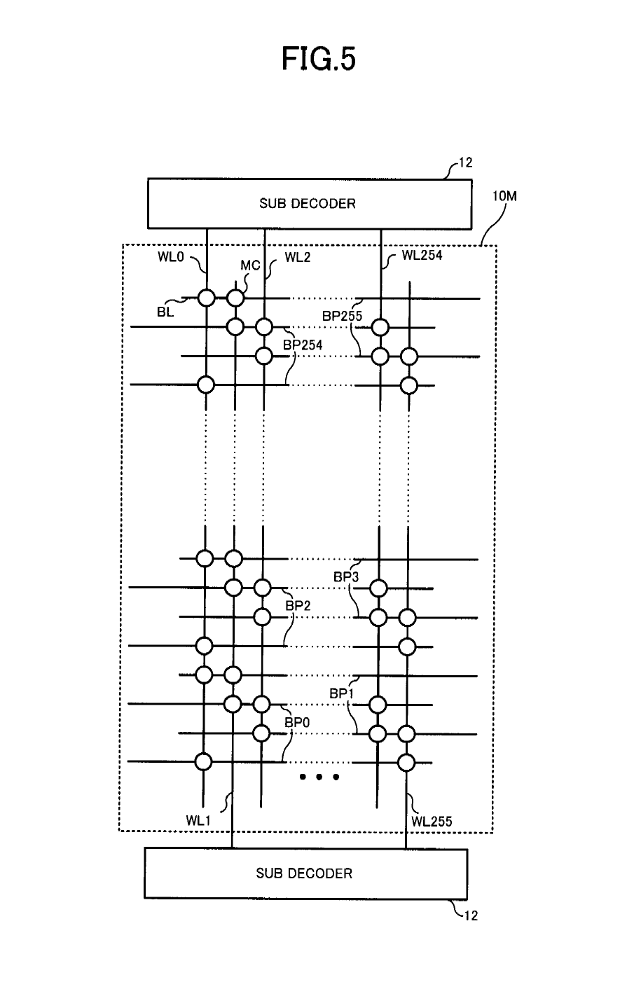

Although the LUT 10 using the DRAM is assumed in the example of FIG. 4, the LUT 10 can be configured using other memory circuits. FIG. 5 shows a modification corresponding to FIG. 4, in which a configuration of the memory cell array 10 using a memory circuit without the sense amplifiers SA of FIG. 4. In the memory cell array 10M of FIG. 5, the respective arrangements of the word lines WL, the bit lines BL, the bit line pairs BP and the memory cells MC are the same as those in FIG. 4 except that the sense amplifiers SA on the both sides are not provided. The configuration of FIG. 4 is assumed to use, for example, DRAM, however the configuration of FIG. 5 is assumed to use, for example, SRAM. When reading the memory cell MC of the SARM, it is possible to supply a signal which is sufficient to directly drive the output latch circuit 16 through the bit lines BL, and therefore the sense amplifiers SA need not to be provided.

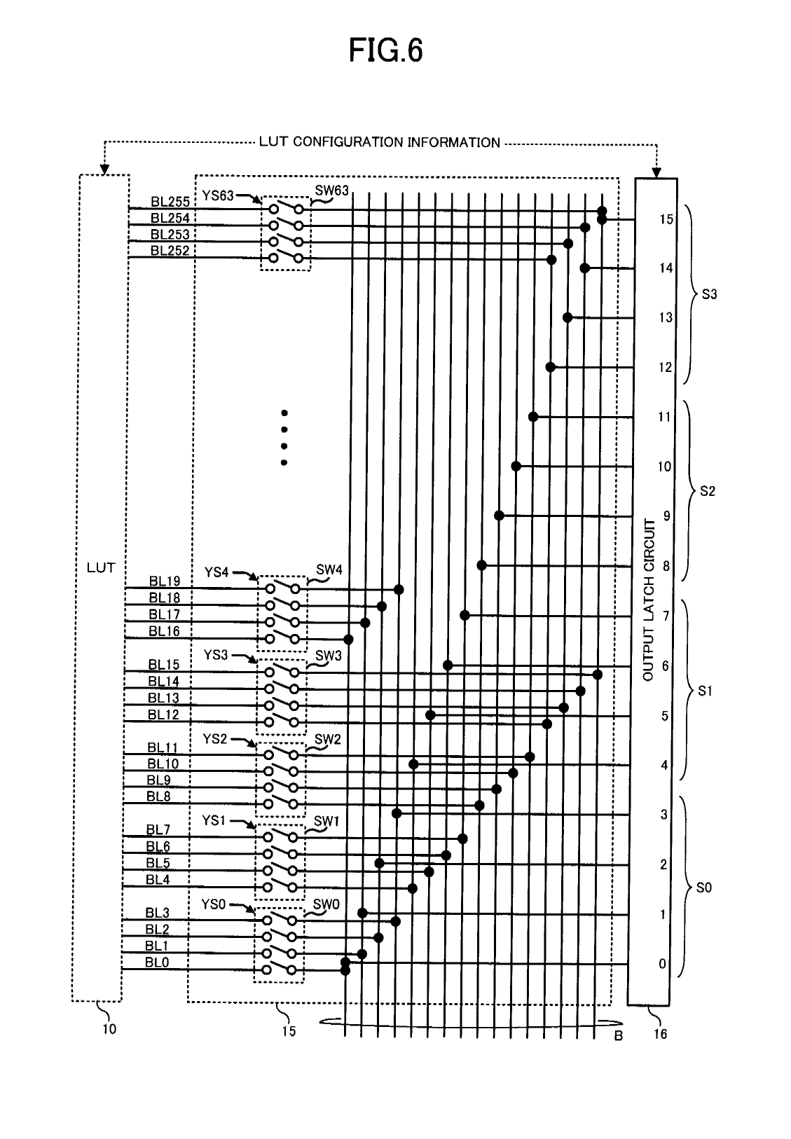

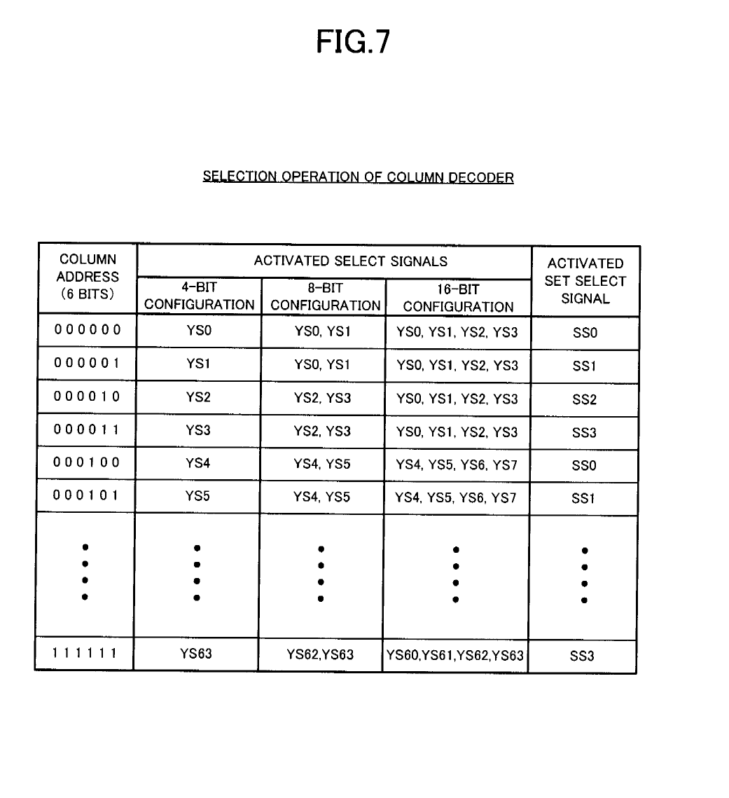

Next, configuration and operation of the output switch circuit 15 on the output-side of the LUT 10 will be described, with relations with the column decoder 13 and the output latch circuit 16 with reference to FIGS. 6 and 7. FIG. 6 is a diagram showing a schematic configuration of the output switch circuit 15, and FIG. 7 is a diagram showing selection operation of the column decoder 13. As shown in FIG. 6, the output switch circuit 15 includes 64 switches SW (denoted as SW0 to SW63) each of which is connected to successive four bit lines among 256 bit lines BL (denoted as BL0 to BL255) represented with numbers. Here, if the LUT 10 has the configuration shown in FIG. 4, each of the 256 bit lines BL0 to BL255 corresponds to one bit line BL of each complementary pair of 256 bit line pairs BP. In addition, a configuration of connection to both bit lines BL of each complementary pair of the 256 bit line pairs BP will be described later.

The 256 bit lines BL0 to BL255 are in a relation in which a set of successive 16 bit lines in the arrangement order is connected to a 16-bit input/output bus B consisting of 16 lines. Meanwhile the 16 lines of the input/output bus B are connected to the output latch circuit 16 of 16 bits in order. Accordingly, data of 16 bit lines BL through the successive four of the switches SW0 to SW63 can be captured in the output latch circuit 16.

In FIG. 6, the 64 switches SW0 to SW63 are controlled to be turned on/off in response to 64 select signals YS (denoted as YS0 to YS63) different from one another. The column decoder 13 selectively activates the 64 select signals YS based on the input variable X1 output from the selector circuit 14. As described above, the bit configuration in the unit LUT circuit of FIG. 1 can be selectively set from the three bit widths (4-bit configuration, 8-bit configuration and 16-bit configuration) based on the LUT configuration information supplied from the LUT configuration memory 21. Thus, selection operations different from one another corresponding to the set input/output bit width are performed in the column decoder 13.

FIG. 7 shows the selection operations of the column decoder 13 corresponding to the three settings of the input/output bit width. When the 4-bit configuration is set, one select signal YS is activated based on all six bits of the input variable X1 as a column address. When the 8-bit configuration is set, two successive select signals YS are activated based on upper five bits of the input variable X1 except the lowermost bit thereof. When the 16-bit configuration is set, four successive select signals YS are activated based on upper four bits of the input variable X1 except lower two bits thereof. Thereby, the switches SW whose number is equal to the number of activated select signals YS are controlled to be on, and four times the number of successive bit lines BL, the maximum number of which is 16, can be connected to the 16 lines of the input/output bus B.

Moreover, the column decoder 13 generates and activates four set select signals SS0 to SS3 based on lower two bits of the input variable X1, in addition to the select signals YS. The set select signals SS0 to SS3 are signals for notifying which sets S0 to S3 are to be selected, which partitions the output latch circuit 16 into portions for every four bits represented such as sets S0, S1, S2 and S3 in the arrangement order. As shown in FIG. 7, the set select signals SS0, SS1, SS2 and SS3 are activated in the order of patterns 00, 01, 10 and 11 of the lower two bits of the input variable X1, and these four patterns are repeated.

In the example of FIG. 6, the output latch circuit 16 is partitioned into a set S0 (0 to 3), a set S1 (4 to 7), a set S2 (8 to 11) and a set S3 (12 to 15), which are denoted by numbers from the lower side. First, when the 4-bit configuration is set, data of four bit lines BL to be accessed are output by one of the sets S0 to S4 corresponding to an activated one of the set select signals SS0 to SS3. When the 8-bit configuration is set, data of eight bit lines BL to be accessed are output by two sets S0 and S1 if any of set select signals SS0 and SS1 is activated, and are output by two sets S2 and S3 if any of set select signals SS2 and SS3 is activated. When the 16-bit configuration is set, data of 16 bit lines BL to be accessed are output by all the sets S0 to S3 regardless of whether or not the set select signals SS0 to SS3 are activated. Accordingly, when capturing data output from the output latch circuit 16, an additional circuit for selecting data based on the set select signals SS0 to SS3 is required for the setting of the 4-bit or 8-bit configuration, while the additional circuit is not required for the setting of the 16-bit configuration. In the first embodiment, a case in which the 16-bit configuration is set will be mainly described.

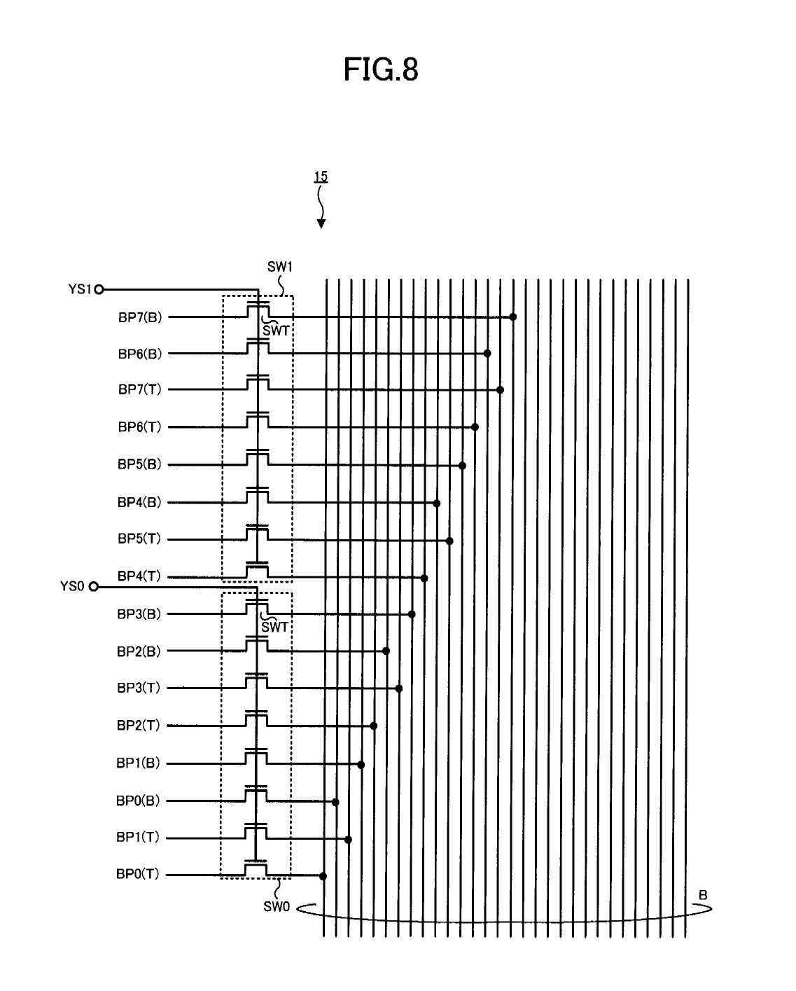

FIG. 8 shows a specific configuration example of the output switch circuit 15 of FIG. 6. A circuit portion corresponding to two switches SW0 and SW1 in lower side of the output switch circuit 15 is only shown in the configuration example of FIG. 8. As shown in FIG. 8, switch transistors SWT are connected to both the two bit lines BP of each bit line pair BP as the complementary pair. For example, the respective switch transistor SWT is connected to a bit line BP0 (T) on a true side and a bit line BP0(B) on a bar side, respectively arranged on every other line corresponding to a first bit line pair BP. Other bit line pairs BP are arranged in the same relation, and each of the switches SW0 and SW1 consists of eight switch transistors SWT. The select signal YS0 is applied to gates of the switch transistors SWT of the switch SW0, and the select signal YS1 is applied to gates of the switch transistors SWT of the switch SW1. Meanwhile, the input/output bus B consists of 32 lines, the number of which is twice that in FIG. 6, corresponding to the bit line pairs BP as the complementary pairs. However, data transmitted through the input/output bus B is actually 16 bits, and therefore 16 bits of one of the complementary pair may be finally captured. Meanwhile, by using this configuration, it is possible to perform read or write operation of the memory cell array 10M directly through the input/output bus B, a path of which is different form that of the logic function, thereby accessing the memory cell array 10M in the same manner as for the general DRAM.

Next, a circuit configuration of the two sub decoders 12 attached to the LUT 10 will be described with reference to FIG. 9. As shown in FIG. 9, the upper sub decoder 12 includes 128 select transistors ST connected to 128 even numbered word lines WL, and the lower sub decoder 12 includes 128 select transistors ST connected to 128 odd numbered word lines WL. FIG. 9 shows part of the circuit of each sub decoder 12, in which the four select transistors ST form a set and the respective select transistors ST are connected between different word lines WL and a common main word line MWL0 so as to be controlled to be turned on/off. In the example of FIG. 9, connections between the common main word line MWL0 and the eight word lines WL0 to WL7 can be controlled by the two sub decoders 12. In each sub decoder 12 as a whole, the same arrangements are repeated, and 32 main word lines MWL can be connected to 256 word lines WL in total, in which each main word line MWL is connected to four word lines WL.

Two predecoders PD are arranged at ends of the two sub decoders 12. These predecoders PD selectively activate eight decode signals D0 to D7 based on the 3-bit input variable X2 output from the selector circuit 14. Each of the decode signals D0 to D3 is coupled to a gate of a different select transistor ST of each set in the lower sub decoder 12, and is used for on/off controlling of the 32 select transistors ST. Similarly, each of the decode signals D4 to D7 is coupled to a gate of a different select transistor ST of each set in the upper sub decoder 12, and is used for on/off controlling of the 32 select transistors ST.

In the two sub decoders 12, one bit of the input variable X2 is used to select the upper or lower sub decoder 12, and the remaining two bits thereof are used to select four select transistors ST in each arrangement. Thus, one of the eight decode signals D0 to D7 is only activated corresponding to a predetermined input variable X2. In this case, since one main word line MWL is selected by the main row decoder 11, one word line WL corresponding to the selected main word line MWL is selected by the two sub decoders 12. In addition, the two sub decoders 12 can be arranged together at one end in a word line extending direction, but the configuration of FIG. 9 is advantageous for loosening the circuit arrangement relative to the pitch of the word lines WL.

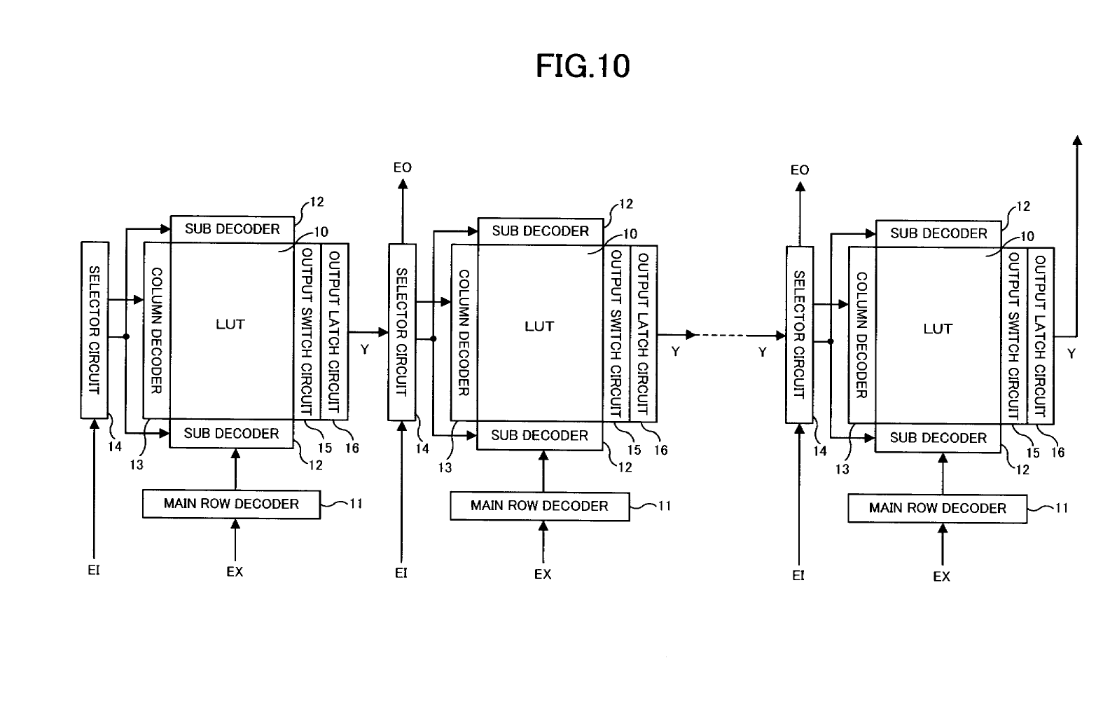

Next, the LUT cascade circuit in which the unit LUT circuits of the first embodiment are connected in multiple stages in cascade will be described. FIG. 10 shows a configuration example of the LUT cascade circuit in which N unit LUT circuits are connected sequentially. In an arbitrary unit LUT circuit of the LUT cascade circuit, the 9-bit external input variable EI is input to the selector circuit 14 from outside and the 5-bit external input variable EX is input to the main row decoder 11. Further, each selector circuit 14 of the unit LUT circuit of the second or further stage sequentially receives the 16-bit output variable Y from the output latch circuit 16 of the preceding stage, and outputs the 16-bit external output variable EO to outside. The 16-bit output variable Y can be extracted from the unit LUT circuit of the last stage.

In FIG. 10, the connection information is supplied to each unit LUT circuit from the connection memory 20 (not shown in FIG. 10). The shift amount included in the connection information can be individually set for each unit LUT circuit, and desired connection form of the logic function can be freely achieved by operation of each selector circuit 14. For example, if the shift amount of the selector circuit 14 is set to 16, upper 9 bits of the 16-bit data output from the unit LUT circuit of the preceding stage can be transmitted to the unit LUT circuit of the subsequent stage. Reversely, if the shift amount of the selector circuit 14 is set to 0, data is not transmitted from the unit LUT circuit of the preceding stage to the unit LUT circuit of the subsequent stage, and the cascade connection is broken off halfway, which means the logic function is terminated at this position.

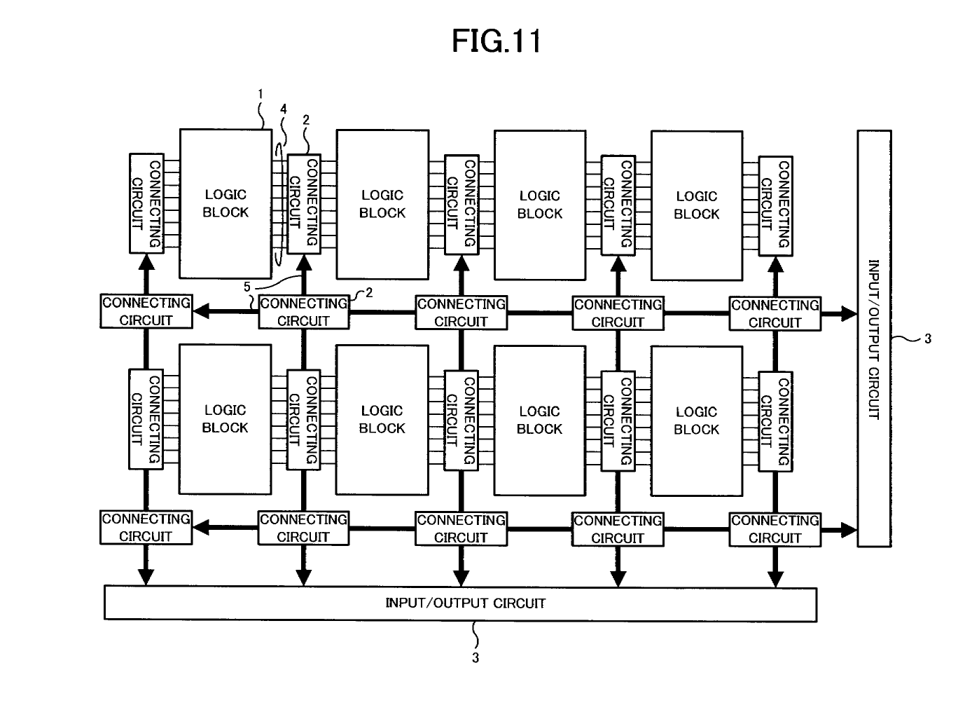

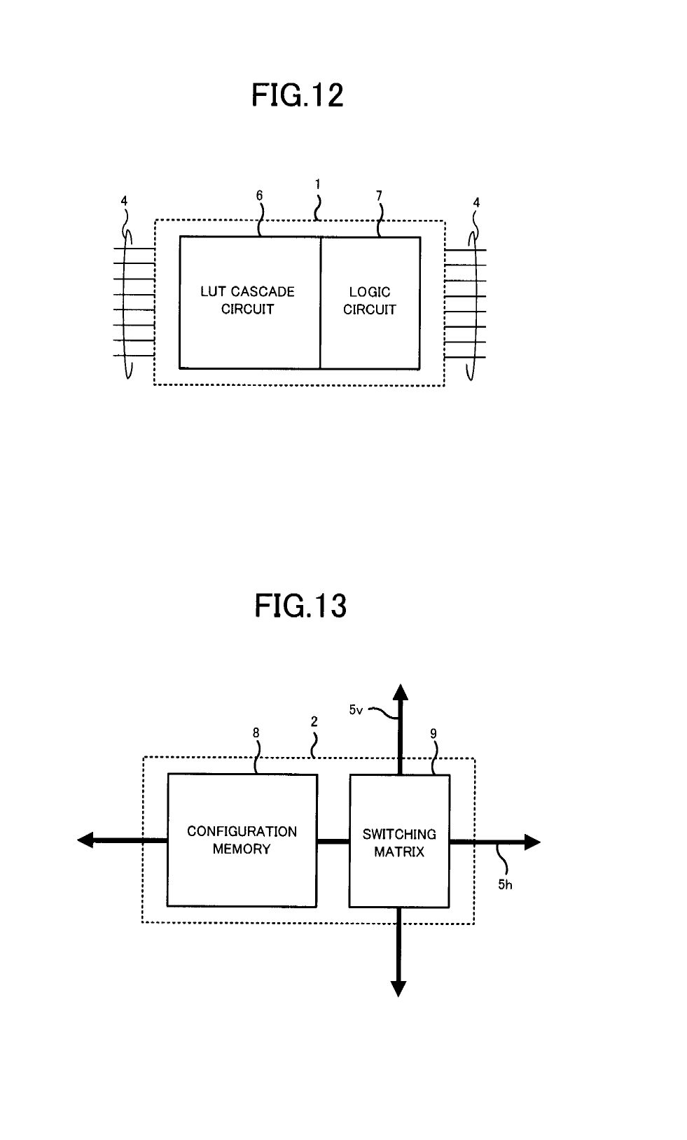

Next, a semiconductor device having a function achieved by the LUT cascade circuit of the first embodiment will be described. FIG. 11 is a block diagram showing an entire configuration of a programmable logic LSI as an example of such a semiconductor device. The programmable logic LSI as shown in FIG. 11 includes a plurality of logic blocks 1 each serving as a predetermined function, a plurality of connecting circuits 2 for switching connection paths of data input/output to/from the logic blocks 1, two input/output circuits 3 for inputting/outputting data between inside and outside the semiconductor device. Further, input/output lines 4 connecting between the logic blocks 1 and the connecting circuits 2, and a connection bus 5 connecting between the connecting circuits 2 and between each connecting circuit 2 and each input/output circuit 3 are arranged. FIGS. 12 and 13 show configurations of the logic block 1 and the connecting circuit 2, respectively included in the configuration of FIG. 11.

The logic block 1 is a circuit for achieving a predetermined function represented by the logic function implemented by the LUT cascade circuit of the first embodiment. As shown in FIG. 12, the logic block 1 includes a LUT cascade circuit 6 including a plurality of unit LUT circuits and a logic circuit 7 for performing a predetermined logic operation. The LUT cascade circuit 6 is configured as in FIG. 10, for example. In the logic block 1, the logic circuit 7 controls the LUT cascade circuit 6 so as to perform an operation of the desired logic function. Further, the logic block 1 is configured so as to transmitting a predetermined number of bits from/to outside through the input/output lines 4. In addition, FIG. 12 shows an example in which eight lines are included in the input/output lines 4, but the actual bit width changes according to a circuit configuration.

As shown in FIG. 13, the connecting circuit 2 includes a configuration memory 8 for storing configuration data, and a switching matrix 9 having a large number of switches arranged in matrix form. Connection state of the switch matrix 9 is designated based on the configuration data stored in the configuration memory 8. In the switch matrix 9, the large number of switches can be selectively connected to a horizontal connection bus 5h or a vertical connection bus 5v in accordance with the designated connection state. The horizontal connection bus 5h has lines extending in a horizontal direction, and the vertical connection bus 5v has lines extending in a vertical direction. In this case, the connection state of the switching matrix 9 can be freely changed by rewriting the configuration data of the configuration memory 8.

Returning to FIG. 11, ten of twenty connecting circuits 2 are connected to the logic blocks 1 adjacent in the horizontal direction through the input/output lines 4, and the remaining ten connecting circuits 2 are connected to the connecting circuits 2 and the input/output circuits 3 adjacent in the horizontal or vertical direction through the connection bus 5. By such connections, data can be transferred between an arbitrary logic block 1 and the outside through the plurality of connecting circuits 2 and the input/output circuit 3.

Although the example of the programmable logic LSI in FIG. 11 includes eight logic blocks 1 and twenty connecting circuits 2, the number of the logic blocks 1 and the number of the connecting circuits 2 can be freely selected. Further, the arrangement and the connection form of the logic blocks 1, the connecting circuits 2 and the input/output circuits 3 are not limited to FIG. 11, and can be variously selected.

By using the above described LUT cascade circuit of the first embodiment, a mechanism of a general memory circuit such as DRAM is utilized, and a desired input variable can be given to each LUT 10 while a desired output variable can be derived from each LUT. The input variable is distributed to the main row decoder 11, the sub decoders 12 and the column decoder 13, the output variable read from selected memory cells MC can be selectively extracted through the output switch circuit 15 and the output latch circuit 16, and it is possible to configure with a small scale circuit added to a conventional memory circuit. Further, since the selector circuit 14 is arranged between adjacent unit LUTs, a relation between the transmission of internal signals and the external input/output can be flexibly switched. For example, if the unit LUT is configured by a general DRAM, the LUT cascade circuit in which large scale and highly integrated LUTs are connected in multiple stages can be implemented in a small area. Further, since signals are transmitted along a shortest path in the LUT cascade circuit, latency can be shortened. Furthermore, since writing to the memory cell array 10M can be performed along a path different from that of data of the logic function using the input/output bus B connected to the output switch circuit 15, contents of the LUT can be rapidly and easily changed.

### Second Embodiment

In a second embodiment, a case will be described in which a plurality of LUT cascade circuits each having a plurality of LUTs connected in multiple stages is implemented and pipeline control is performed. In the second embodiment, the basic form of the unit LUT circuit are almost common to those of the first embodiment, and configuration and operations are the same as those in FIGS. 1 to 8, so description thereof will be omitted. Meanwhile, in the unit LUT circuit of the second embodiment, a circuit configuration on the periphery of the two sub decoders 12 attached to the LUT 10 is different from that in the first embodiment.

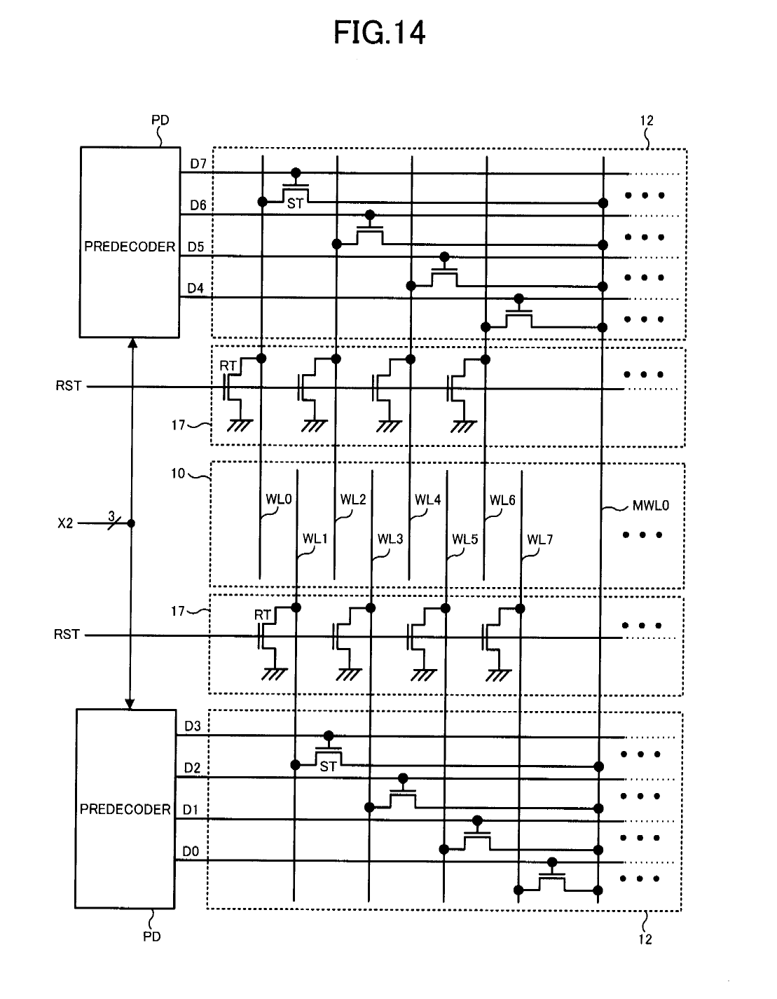

FIG. 14 is a diagram showing the circuit configuration of the two sub decoders 12 and its periphery in the second embodiment. The circuit configuration of each sub decoder 12 itself and the function of the two predecoders PD are the same as in the first embodiment. On the other hand, two reset circuits 17 adjacent to the two sub decoders 12 are provided in FIG. 14. Each reset circuit 17 includes a plurality of reset transistors RT having commonly connected gates to which a reset signal RST is applied. The reset signal RST is supplied from a control circuit (not shown) in the unit LUT circuit. In the two reset circuits 17, 256 reset transistors RT are arranged in parallel, the number of which is the same as of the select transistors. The respective reset transistors RT are connected between word lines WL different from one another and ground, and are controlled to be turned on/off in response to the reset signal RST.

When the reset signal RST is low, each reset transistor PT turns off, which does not affect a state of each word line WL. When the reset signal RST is high, each reset transistor RT turns on, and each word line WL is forced to be low. In this manner, the role of the reset circuit 17 is to reset one word line WL at a predetermined timing based on the pipeline control when the word line WL corresponding to one main word line MWL is in an activated state. Thereby, control for sequentially activating a plurality of word lines WL can be rapidly performed.

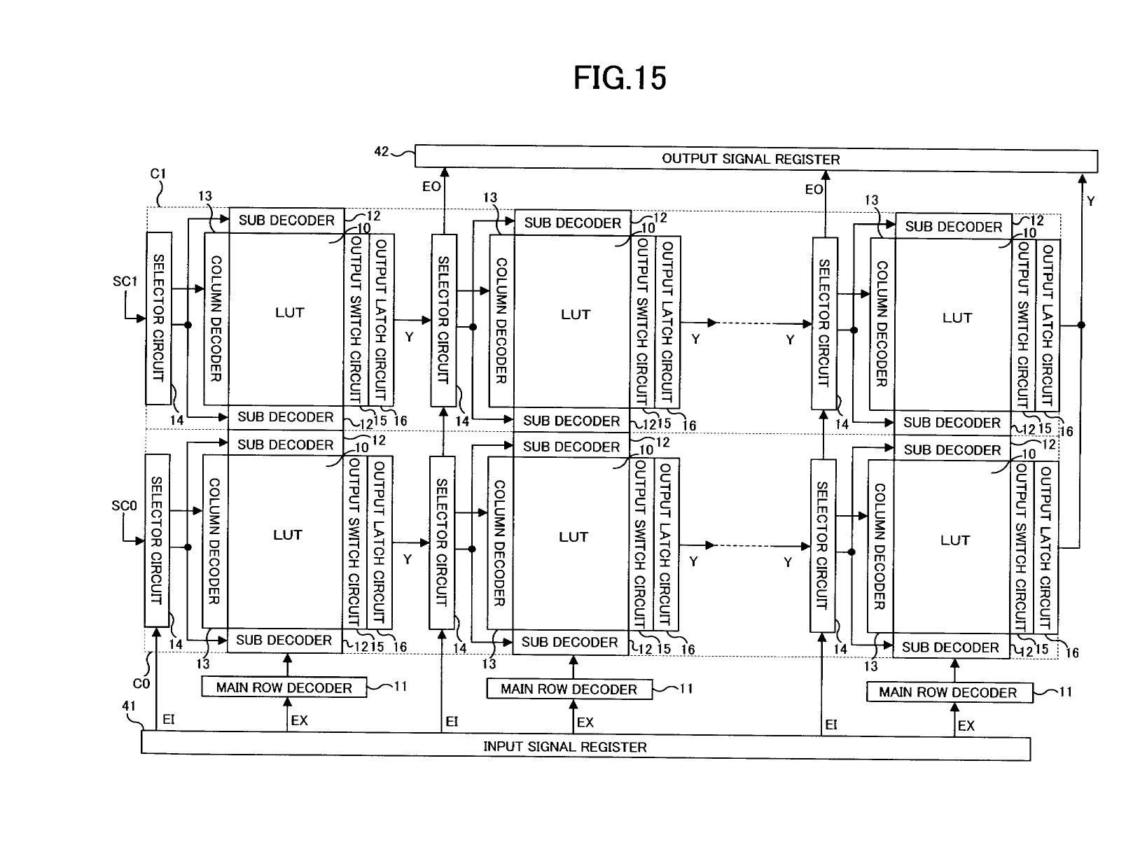

Next, a LUT cascade array circuit will be described in which the LUT cascade circuits having the unit LUT circuits of the second embodiment connected in multiple stages in cascade are arranged in an array form. FIG. 15 shows a configuration example of a LUT cascade array circuit in which two LUT cascade circuits each having N unit LUT circuits connected sequentially are arranged in the array form. Since the pipeline control is performed in the second embodiment, it is assumed that a plurality of LUT cascade circuits for achieving different functions from each other is arranged. In two LUT cascade circuits C0 and C1 of FIG. 15, cascade select signals SC0 and SC1 are supplied to the first-stage unit LUT circuits respectively, and one of the LUT cascade circuits C0 and C1 can be selected in response to the cascade select signals SC0 and SC1. In addition, M LUT cascade circuits can be actually arranged, however a case of M=2 will be described for simplicity.

In the configuration of FIG. 15, there are provided an input signal register 41 for storing the external input variable EI input to each unit LUT circuit and the external input variable EX, and an output signal register 42 for storing the external output variable EO output from each unit LUT circuit of the second or further stage and the output variable Y output from the unit LUT circuit of the last stage. In two unit LUT circuits in a longitudinal direction of FIG. 15, the external input variables EI and EX are transmitted along common paths, and the external output variable EO and the output variable Y of the last stage are also transmitted along common paths. Thus, the input/output from/to the two unit LUT circuits in the longitudinal direction should be controlled at different timings.

Further, N LUTs 10 aligned in a lateral direction of FIG. 15 are constituent elements included in the common LUT cascade circuit C0 or C1, and have the same connection relation as that in FIG. 10. Meanwhile, the two LUTs 10 in the longitudinal direction arranged at the same lateral position are included different LUT cascade circuits C0 and C1, but share one main row decoder 11, and in which a plurality of main word lines MWL are commonly arranged. Thus, each main word line MWL can be selectively connected to eight word lines WL in the upper LUT 10 and eight word lines WL in the lower LUT 10. However, different external input variables EI and different external input variables EX are given to the upper and lower LUT cascade circuits, and therefore the two LUTs 10 in the longitudinal direction cannot be accessed simultaneously. In this manner, the configuration of FIG. 15 is suitable for the pipeline control enabling the two LUT cascade circuits C0 and C1 to be operated at different timings.

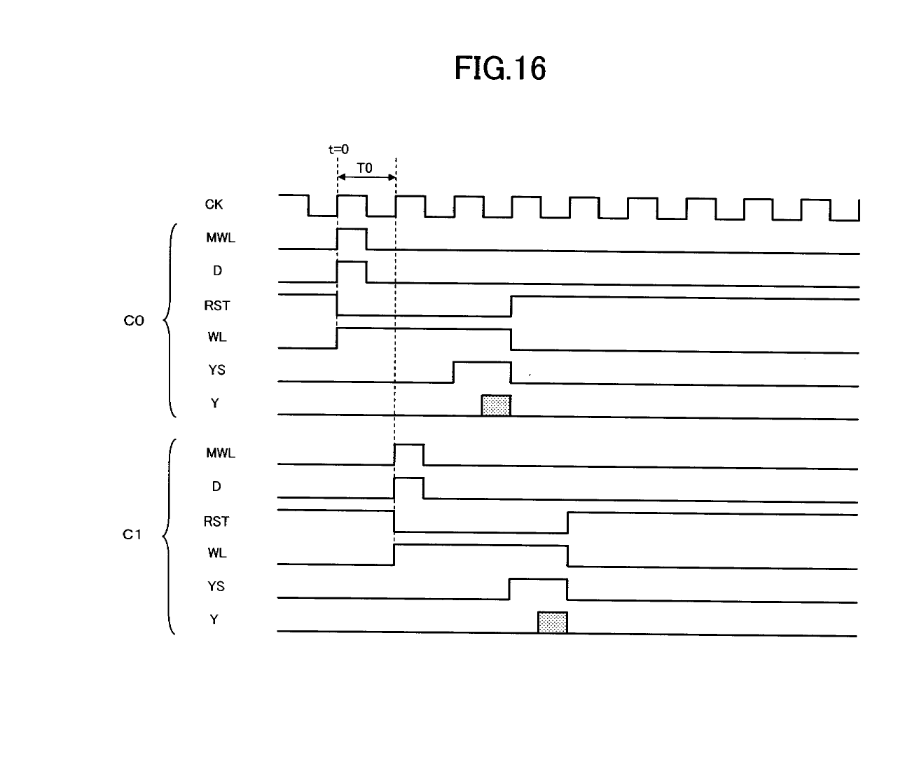

Next, the pipeline control for the two LUT cascade circuits C0 and C1 of FIG. 15 will be described. FIG. 16 shows a waveform diagram corresponding to the pipeline control, in which a read operation for the two LUTs 10 adjacent in the longitudinal direction of FIG. 15 is exemplified. The pipeline control of the second embodiment is performed in synchronization with a clock CK having a predetermined period T0. The read operation for a LUT 10 in the LUT cascade circuit C0 is started at a time t=0.

A predetermined main word line MWL is activated in response to the external input variable EX at the time t=0, and a predetermined decode signal D is activated in response to an address signal from the selector circuit 14. Thereby, a word line WL to be accessed in the LUT 10 is activated. At this point, the reset signal RST supplied to the reset circuit 17 changes to low, and the reset state of the word line WL is cancelled. Then, the main word line MWL and the decode signal D change to low at a time t=0.5T0, the level of the word line WL at this time is held by parasitic capacitance.

Thereafter, each memory cell MC is amplified by each sense amplifier SA at a predetermined timing, and 16-bit data read from memory cells to be accessed is fixed. Subsequently, after a predetermined time elapsed, a predetermined select signal YS supplied to the switch circuit 15 changes to high, and four successive switches SW are controlled to be on. Thereby, 16 bit lines BL to be accessed are connected to the input/output bus B and transmitted as the 16-bit output variable Y to the subsequent stage. The reset signal RST changes to high for a next read operation for the LUT 10 at a time t=3T0 thereby resetting the word line W, and the select signal YS returns to an inactivated state.

Meanwhile, at a time t=T0 which is delayed one cycle from the read operation for the LUT cascade circuit C0, a read operation for the LUTs 10 in the LUT cascade circuit C1 is started. Each signal waveform of the LUT cascade circuit C1 is delayed only one cycle from that of the LUT cascade circuit C0, and changes in the same pattern. As understood from FIG. 16, the read operation of the LUT 10 is not finished at the time t=T0 in the LUT cascade circuit C0, but the main word line MWL and the decode signal D have returned to the inactivated state. Thus, in the LUTs 10 of the two LUT cascade circuits C0 and C1, word lines WL different from each other can be selected by setting the respective operations to be shifted one cycle relative to each other. Also, different data can be transmitted through the input/output bus B by setting the respective operations to be shifted one cycle relative to each other.

Although the pipeline control for the two LUT cascade circuits C0 and C1 is shown in FIG. 16, a case in which a larger number of LUT cascade circuits are arranged can be considered in the same manner. That is, read operations for the LUTs 10 at the same lateral position may be performed by delaying one cycle for each operation sequentially one by one. By adopting the pipeline control, the reading speed can be substantially higher than that for a case in which only a single LUT cascade circuit is operated, so that the throughput can be improved.

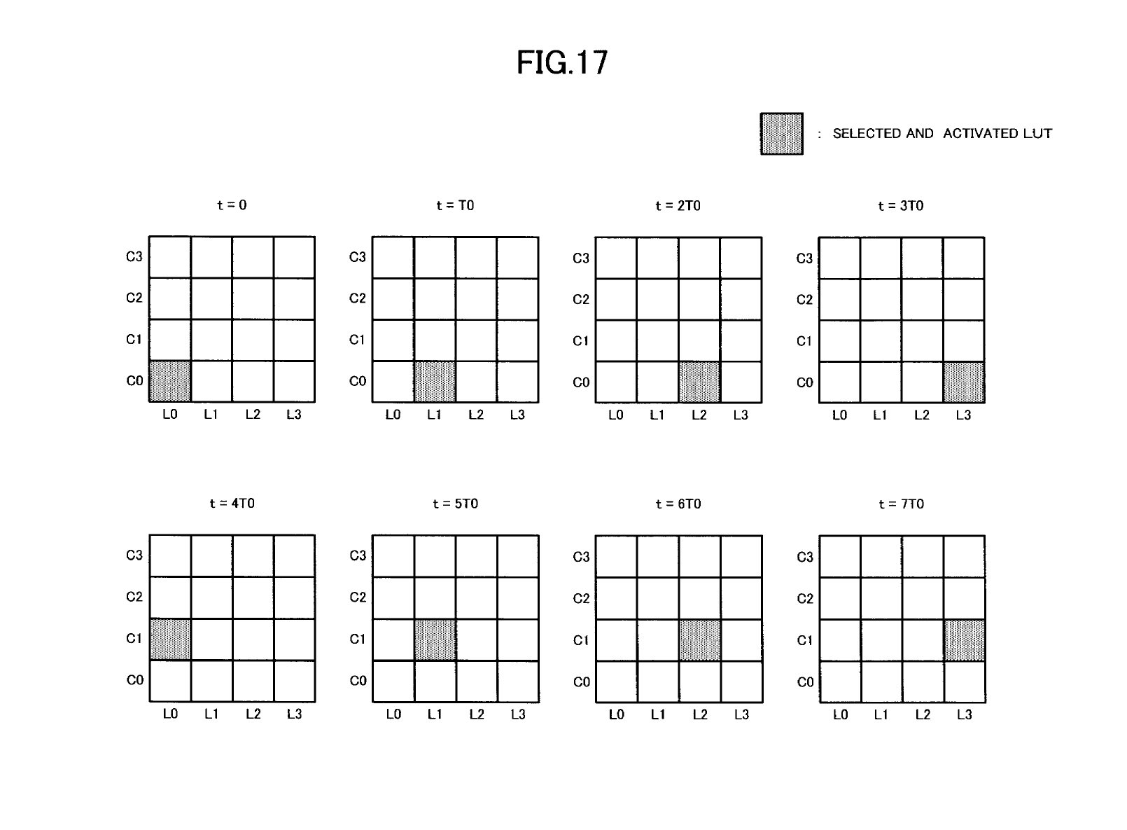

Next, a temporal transition of read operations for the unit LUT circuits constituting a plurality of LUT cascade circuits in performing the pipeline control will be described with reference to FIGS. 17 to 19. In the following, a case is exemplified for simplicity, in which each of four LUT cascade circuits includes four unit LUT circuits thereby reading from 16 LUTs 10 in total. FIGS. 17 to 19 represents a configuration in matrix form in which the four LUT cascade circuits C0, C1, C2 and C3 are arranged in parallel in the longitudinal direction and each of the LUT cascade circuits C0 to C3 includes four LUTs L0, L1, L2 and L3 aligned in the lateral direction. Further, eight steps of the control states at respective times starting from the time t=0 and increasing step by step by the period T0 are represented.

In FIG. 17, a temporal transition of control states in a case in which the pipeline control is not performed is shown for the purpose of comparison. The first LUT L0 of the LUT cascade circuit C0 is accessed at t=0. Subsequently, as the time elapses such as t=T0, 2T0 and 3T0, the LUT L1, L2, L3 of the LUT cascade circuit C0 are accessed in this order, and the output variable Y of the last LUT L3 is fixed. Meanwhile, the LUT cascade circuit C1 is not accessed within a time range from t=0 to 3T0, and the first LUT L0 thereof is accessed at t=4T0 after reading of the LUT cascade circuit C0 is finished. Thus, the LUT cascade circuit C1 is only accessed within a time range from t=4T0 to 7T0. The same control is thereafter performed, two LUT cascade circuits are not accessed simultaneously, and accesses for the four LUT cascade circuits C0 to C3 are finished at a time t=16T0.

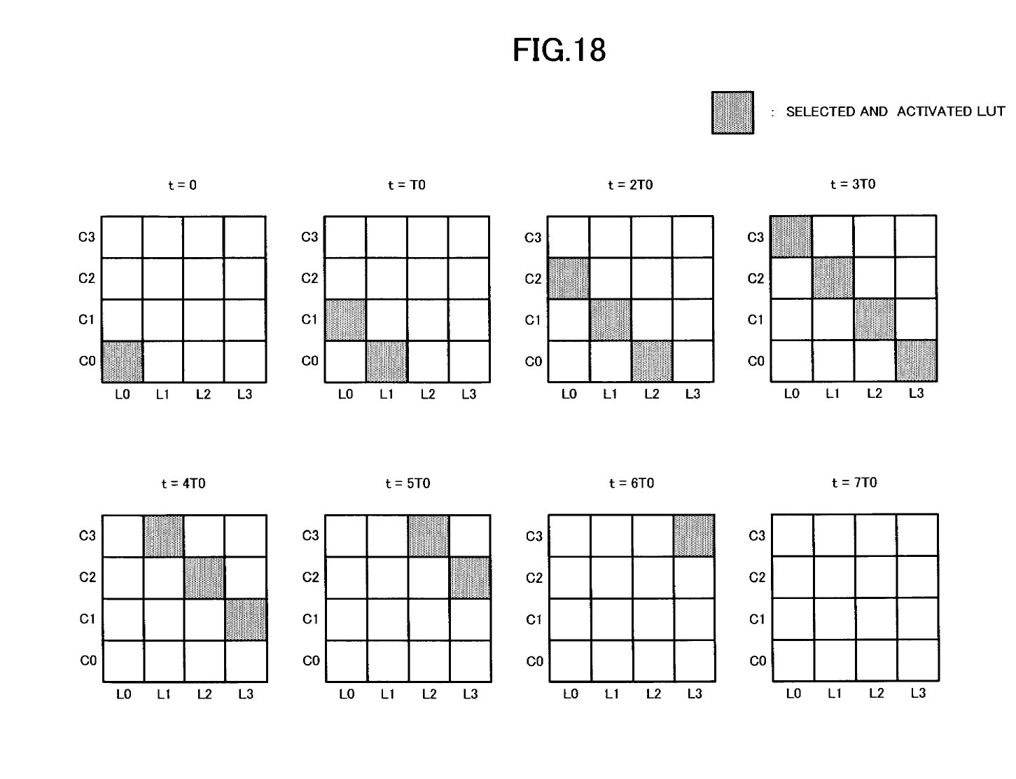

FIG. 18 shows a temporal transition of control states in a case in which each of the LUT cascade circuits C0 to C3 is operated one time by the pipeline control. The first LUT L0 of the LUT cascade circuit C0 is accessed at t=0 as in FIG. 17. On the other hand, the second LUT L1 of the LUT cascade circuit C0 and the first LUT L0 of the LUT cascade circuit C1 are accessed simultaneously at t=T0. Similarly, three LUTs 10 at different positions of the three LUT cascade circuits C0, C1 and C2 are accessed simultaneously at t=2T0, and four LUTs 10 at different positions of the four LUT cascade circuits C0 to C3 are accessed simultaneously at t=3T0. Subsequently, operations of the LUT cascade circuits C0 to C3 are finished in this order within a time range from t=4T0 to t=7T0, and the number of LUTs which are accessed simultaneously decrease to 3, 2, 1, so that the entire access has been finished at t=7T0.

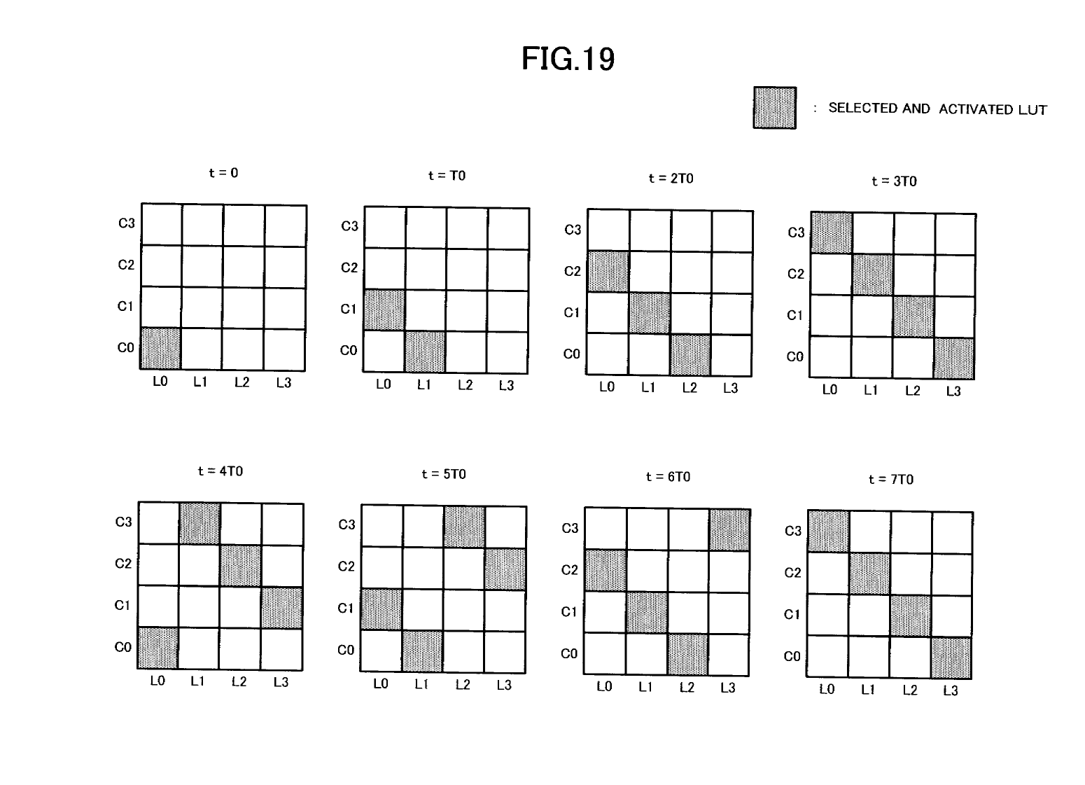

FIG. 19 shows a temporal transition of control states in a case in which the LUT cascade circuits C0 to C3 are repeatedly operated by the pipeline control. This case has the same temporal transition within a time range from t=0 to t=3T0 as in FIG. 18. On the other hand, a second operation of the LUT cascade circuit C0 is started at t=4T0, a first operation of which has been finished at t=3T0, so that the first LUT L0 thereof is accessed. Subsequently, second operations of the LUT cascade circuits C1, C2 and C3 are sequentially started at subsequent timings after the first operations are finished. Thus, four LUTs 10 of the four LUT cascade circuits are always in a state of being accessed after t=3T0. The control in FIG. 19 is repeated until being forced to finish the operation by a predetermined command or the like.

By comparing the pipeline control in FIGS. 18 and 19 with that in FIG. 17, it is common that the operation of each of the LUT cascade circuits C0 to C3 takes four cycles, however the number of cycles for operating all the four LUT cascade circuits C0 to C4 can be sufficiently shortened. That is, parallel accesses to the four LUT L0 to L3 at different positions from one another of the four LUT cascade circuits C0 to C3 can be performed at each timing, therefore the average number of cycles converges to ¼. Particularly, when M LUT cascade circuits each having N LUTs 10 are arranged, it is advantageous to adopt the pipeline control as the circuit scale becomes larger. In addition, when performing the pipeline control for the M LUT cascade circuits, correspondingly M input signal registers 41 and M output signal registers 42 are desired to be arranged in terms of easiness in control.

By using the above described LUT cascade array circuit of the second embodiment, the pipeline control for operating a plurality of LUT cascade circuits of the first embodiment in parallel can be achieved. In this case, the unit LUT circuits at the same position of each LUT cascade circuit can share the main word line MWL by arranging one main row decoder 11 using the word line hierarchy structure, thereby achieving an efficient circuit in a small area. Further, by operating the LUT cascade circuits in parallel according to the pipeline control, effective processing speed of the logic operation can be improved.

In the foregoing, contents of the present invention have been specifically described based on the two embodiments. However, the present invention is not limited to the above two embodiments, and can be variously modified without departing the essentials of the present invention. In the above embodiments, a case to which the present invention is applied using a DRAM circuit as a memory circuit has been described. However, the present invention can be widely applied to cases of using a SRAM circuit or a nonvolatile RAM circuit. Further, a circuit having the configuration of the present invention can be achieved in semiconductor devices having various uses and functions.

The present invention is not limited to the above described embodiments, and various variations and modifications may be possible without departing from the scope of the present invention.

This application is based on the Japanese Patent application No. 2006-313637 filed on Nov. 20, 2006, entire content of which is expressly incorporated by reference herein.

What is claimed is:

1. A look-up table cascade circuit having N (N is an integer greater than or equal to two) look-up tables connected in cascade for implementing a desired logic function, comprising:
N memory cell arrays each for storing data of each said look-up table in a plurality of memory cells formed at intersections between a plurality of word lines and a plurality of bit lines;
N input select circuits each for selecting a word line and one or more bit lines to specify one or more memory cells to be read in each said memory cell array based on an input variable to each said look-up table;
N output circuits each for selectively coupling data of a predetermined number of bits in the memory cells selected by each said input select circuit to an input/output path and for outputting the data as an output variable of each said look-up table; and
N−1 connection circuits arranged between each preceding said output circuit and each subsequent said input select circuit respectively included in stages connected in cascade, each for receiving an external input variable and the output variable output from each preceding said output circuit, and each for selectively distributing all or part of an external output variable and the input variable to be supplied to each subsequent said input select circuit based on preset connection information.

2. The look-up table cascade circuit according to claim 1, wherein each said connection circuit includes:
an input register for storing the external input variable and the external output variable;
a shifter circuit for shifting data stored in the input register by a shift amount included in the connection information; and
an output register for storing the data shifted by the shifter circuit and for outputting the external output variable and the input variable.

3. The look-up table cascade circuit according to claim 1, wherein each said input select circuit includes:
a row decoder for selectively activating the plurality of word lines; and
a column decoder for selecting a predetermined number of the bit lines to specify the memory cells to be read.

4. The look-up table cascade circuit according to claim 3,
wherein a word line hierarchy structure including a plurality of main word lines and a plurality of sub-word lines is formed in said memory cell array,
and the row decoder includes a main row decoder for selectively activating the plurality of main word lines and one or more sub decoders for selectively activating the plurality of sub-word lines.

5. The look-up table cascade circuit according to claim 4, wherein the input variable comprises a first input variable input from the connection circuit to the column decoder, a second input variable input from the connection circuit to the sub decoders, and a third variable input form outside to the main row decoder.

6. The look-up table cascade circuit according to claim 4, wherein two sub decoders are arranged symmetrically at both ends in a word line extending direction of each said memory cell array, and the plurality of sub-word lines is alternately connected to the sub decoders.

7. The look-up table cascade circuit according to claim 1, wherein said output circuit includes an output switch circuit for selectively connecting a predetermined number of the bit lines selected by said input select circuit to the input/output path, and an output latch circuit for latching the output variable through the input/output path.

8. The look-up table cascade circuit according to claim 7, wherein data can be input or output from/to said memory cell array along a path through the input/output path which is different from a path through the output latch circuit.

9. The look-up table cascade circuit according to claim 7, wherein an input/output bit configuration of said memory cell array can be changed within a range of bit widths of the input/output path.

10. The look-up table cascade circuit according to claim 1, wherein said N look-up tables are configured using N DRAM circuits.

11. A look-up table cascade array circuit having M (M is an integer greater than or equal to two) look-up table cascade circuits according to claim 1 arranged in an array form in a word line extending direction,
wherein in M said memory sell arrays at the same position of different said look-up table cascade circuits, the external input variable is transmitted along a common path and the external output variable is transmitted along a common path.

12. A look-up table cascade array circuit having M (M is an integer greater than or equal to two) look-up table cascade circuits according to claim 4 arranged in an array form in a word line extending direction,
wherein M said memory sell arrays at the same position of different said look-up table cascade circuits share the plurality of main word lines, and a selected main word line is activated in response to the input variable commonly input from outside.

13. A pipeline control method of a look-up table cascade array circuit for performing pipeline control for the look-up table cascade array circuit according to claim 11 or 12 in a predetermined order, comprising the steps of:
performing operations for two said look-up tables at the same position of two successive said look-up table cascade circuits, including the steps of:
performing a first operation in which a first look-up table is selected to operate said input select circuit at a first timing, and the output variable is output from said output circuit so as to be transmitted to a subsequent stage after a predetermined delay time elapses from the first timing; and
performing a second operation in which a second look-up table is selected to operate said input select circuit at a second timing before the predetermined delay time elapses, and the output variable is output from said output circuit so as to be transmitted to a subsequent stage after a predetermined delay time elapses from the second timing;
and repeating the operations for all the look-up tables in the same manner, in which the first operation is performed for each preceding look-up table and the second operation is performed for each subsequent look-up table.

14. The pipeline control method according to claim 13, wherein the first and second operations for each of said M look-up table cascade circuits are controlled in synchronization with a clock signal having a predetermined period, and a time difference between the first and second timings is equal to one period of the clock signal.
